(19) United States
(12) Patent Application Publication
(10) Pub. No.: US 2012/0009763 A1
(43) Pub. Date: Jan. 12, 2012

(54) SEMICONDUCTOR CHIP MANUFACTURING METHOD

(75) Inventor: Vincent Jarry, la Membrolle Sur Choisille (FR)

(73) Assignee: STMicroelectronics (Tours) SAS, Tours (FR)

(21) Appl. No.: 13/105,244

(22) Filed: May 11, 2011

(30) Foreign Application Priority Data
May 12, 2010 (FR) 1053742

(51) Int. Cl. H01L 21/78

(52) U.S. Cl. 438/463; 257/E21.599

(57) ABSTRACT

A method for manufacturing semiconductor chips from a semiconductor wafer, including the steps of: a) arranging the wafer on a surface of an elastic film stretched on a first support frame having dimensions much greater than the wafer dimensions, so that, in top view, a ring-shaped film portion separates this outer contour from the inner contour of the frame; b) performing manufacturing operations by using equipment capable of receiving the first frame; c) arranging, on the ring-shaped film portion, a second frame of outer dimensions smaller than the inner dimensions of the first frame; d) cutting the film between the outer contour of the second frame and the inner contour of the first frame and removing the first frame; and e) performing manufacturing operations by using equipment capable of receiving the second frame.

### CROSS REFERENCE TO RELATED APPLICATIONS

This application claims the priority benefit of French patent application number 10/53742, filed on May 12, 2010, entitled SEMICONDUCTOR CHIP MANUFACTURING METHOD, which is hereby incorporated by reference to the maximum extent allowable by law.

### BACKGROUND OF THE INVENTION

1. Field of the Invention

The present invention relates to a method for manufacturing semiconductor chips from a semiconductor wafer. It more specifically aims at a manufacturing method comprising a step during which the wafer is diced into individual chips by means of a laser beam.

2. Discussion of the Related Art

The manufacturing of semiconductor chips especially comprises, after steps of forming of components and of interconnect metallizations inside and on top of a semiconductor wafer, a step of dicing of the wafer into individual chips. This dicing is conventionally performed by means of a saw.

FIGS. 1A, 2A and 1B, 2B schematically illustrate steps of a method for dicing a semiconductor wafer 10 into individual chips by means of a saw. FIGS. 1A and 1B are top views and FIGS. 2A and 2B respectively are cross-section views along planes II-II of FIGS. 1A and 1B.

FIGS. 1A and 2A illustrate an initial step in which wafer 10 is arranged on a surface of an adhesive film 12 stretched on a support frame 14. Conventionally, wafer 10 has an approximately circular shape and frame 14 has a circular inner contour with a diameter slightly greater than the diameter of wafer 10. In this example, the general shape of the outer contour of frame 14 is approximately square with rounded corners and comprises location notches 16.

The specific shape of frame 14 enables to accurately position the wafer in various processing machines. In a given production line, frame 14 has standard shape and dimensions and is used at various steps of the chip manufacturing. Thus, many machines are capable of receiving a type of support frame 14, of given shape and dimensions.

FIGS. 1B and 2B illustrate the actual dicing of wafer 10 into individual chips 18. The dicing is conventionally performed by means of a circular saw (not shown) running through the wafer along a grid of lines and columns The dicing is performed across the entire wafer thickness and stops in the upper portion of adhesive film 12, without however cutting this film. As an example, for a wafer having a thickness of approximately 400 the dicing lines have a width of approximately 90 μm. It should be noted that in practice, a semiconductor wafer comprises a much larger number of elementary chips 18 than what has been shown.

After the wafer has been diced, the individual chips remain on frame 14, and other manufacturing steps are provided, during which the diced wafer is processed in machines capable of receiving frame 14. Adhesive film 12 especially enables chips 18 to remain in place during these manufacturing steps and during subsequent transportations of frame 14.

For a more accurate dicing, and especially to decrease the width of dicing lines to minimize losses, it has been provided to perform the dicing by means of a laser beam. The use of a laser beam further enables to more easily dice hard substrates such as sapphire or silicon carbide.

FIGS. 3A, 4A, 3B, 4B, 3C, 4C and 3D, 4D schematically illustrate steps of a method for dicing a semiconductor wafer 20 into individual chips by means of a laser beam. FIGS. 3A, 3B, 3C and 3D are top views and FIGS. 4A, 4B, 4C and 4D respectively are cross-section views along planes IV-IV of FIGS. 3A, 3B, 3C and 3D.

FIGS. 3A and 4A illustrate an initial step during which wafer 20 is arranged on a surface of an adhesive elastic film 22 stretched on a support frame 24. As will be explained in further detail hereafter, especially in relation with FIGS. 3B, 4B, and 3C, 4C, the wafer dicing by means of a laser beam requires the use of a support frame having an inner diameter much greater than the dimensions of the semiconductor wafer. In this example, frame 24 has a shape similar to that of frame 14 of FIGS. 1A and 2A, but greater dimensions.

FIGS. 3B and 4B illustrate the actual chip dicing step.

First, grooves 25 are formed on the free surface of the wafer (here, the upper surface), according to a grid of lines and columns, by means of a laser beam, not shown. Grooves 25 for example go down to a depth approximately ranging from 10 to 250 μm, and have a width approximately ranging from 20 to 40 μm.

Second, the lower surface of the wafer is hit, successively opposite to each of grooves 25, by means of a knife 26. This causes a breakage of the wafer along each groove 25, thus resulting in a dicing of the wafer into individual chips. To enable the passing of knife 26, in particular, the inner diameter of frame 24 must be greater than the wafer dimensions. As an example, for wafers having a 20-centimeter diameter, the inner diameter of frame 24 must be greater by at least from 2 to 3 centimeters than the wafer diameter.

FIGS. 3C and 4C illustrate a step of stretching of elastic film 22, carried out after the step of dicing of the wafer into individual chips 27. During the dicing process described in relation with FIGS. 3B and 4B, the wafer splits across its entire thickness, opposite to each groove 25, but the resulting individual chips 27 remained adjacent to one another. To avoid frictions between chips which might damage their sides and create splinters, chips 27 are separated from one another by an extension of film 22. For this purpose, a pair of concentric circular rings comprising an outer ring 28e and an inner ring 28i, capable of nesting into each other, is used. The outer contour of ring 28e substantially coincides with the inner contour of frame 24, the outer contour of ring 28i substantially coincides with the inner contour of ring 28e, and the inner contour of ring 28i is greater than or equal to the wafer diameter.

To cause the extension of elastic film 22, rings 28e and 28i are placed on either side of the film, after which ring 28e is nested into frame 24 and ring 28i is nested into ring 28e. Film 22 is thus pinched between the outer contour of ring 28i and the inner contour of ring 28e, and its central portion, here delimited by the outer contour of ring 28i, is raised with respect its peripheral portion (opposite to frame 24 and to ring 28e). This results in an extension of elastic film 22, especially in its central portion, thus separating chips 27 from one another.

A disadvantage of this method is the need to use a frame 24 having much greater dimensions than the frame currently used for chip dicing operations (frame 14 of FIGS. 1A and 1B). As a result, for all the manufacturing steps subsequent to the chip dicing, specific processing equipment capable of receiving a frame larger than the usual frame must be provided.

FIGS. 3D and 4D illustrate a step during which frame 24 is removed, for example, by cutting film 22 in the vicinity of the outer contour of extension ring 28e. The pair of extension rings can then be used as a support for the next chip manufacturing steps. Indeed, this support is less bulky than frame 24. However, the shape and dimensions of this new support do not correspond to those of usual frame 14 of FIGS. 1A and 2A. Thus, the equipment used to implement manufacturing steps subsequent to the wafer dicing should be specifically adapted to be compatible with this new support.

### SUMMARY OF THE INVENTION

An embodiment provides a method for manufacturing semiconductor chips from a semiconductor wafer, at least partly overcoming some of the disadvantages of current methods.

An embodiment provides such a method comprising a step during which the wafer is diced into individual chips by means of a laser beam and of a knife.

An embodiment provides a method such that at the end of the dicing, the diced wafer can be processed by using existing equipment capable of receiving a standard support frame.

An embodiment provides such a method which is easy to implement.

An embodiment provides a method for manufacturing semiconductor chips from a semiconductor wafer, comprising the steps of: arranging the wafer on a surface of an elastic film stretched on a first support frame having dimensions much greater than the wafer dimensions, so that, in top view, a ring-shaped film portion separates the outer contour of the wafer from the inner contour of the frame; carrying out manufacturing operations by using equipment capable of receiving the first frame; arranging, on the ring-shaped film portion, a second support frame of outer dimensions smaller than the inner dimensions of the first frame; cutting the film between the vicinity of the outer contour of the second frame and the inner contour of the first frame and removing the first frame; and performing manufacturing operations by using equipment capable of receiving the second frame.

According to an embodiment, the wafer has a generally circular shape, and the first and second frames have circular inner contours of diameters respectively greater than and at least equal to the wafer diameter.

According to an embodiment, the first and second frames have outer contours of generally square shape with rounded corners, with location notches.

According to an embodiment, the manufacturing operations using equipment capable of receiving the first frame comprise an operation of dicing of the wafer into chips by applying a laser beam and by hitting with a knife.

According to an embodiment, these operations further comprise, after the wafer dicing into chips, a step of separation of the chips by extension of the film by means of a pair of extension rings.

According to an embodiment, the ring-shaped film portion has a sufficient width to receive the second frame after the step of separation of the chips by means of the extension rings.

According to an embodiment, the elastic film is an adhesive film.

According to an embodiment, the width of the ring-shaped film portion ranges between 7 and 15 centimeters.

According to an embodiment, the wafers have a diameter of 15 or 20 centimeters.

The foregoing and other objects, features, and advantages will be discussed in detail in the following non-limiting description of specific embodiments in connection with the accompanying drawings.

### BRIEF DESCRIPTION OF THE DRAWINGS

FIGS. 1A, 2A and 1B, 2B, previously described, schematically illustrate steps of a conventional method for dicing a semiconductor wafer into individual chips by means of a saw;

FIGS. 3A, 4A to 3D, 4D, previously described, schematically illustrate steps of a method for dicing a semiconductor wafer into individual chips by means of a laser beam; and

FIGS. 5A, 6A and 5B, 6B schematically illustrate steps of an example of a method for dicing a semiconductor wafer into individual chips by means of a laser beam, this method being such that after the dicing, the chips can be processed by using existing equipment capable of receiving a frame of standard dimensions.

It should be noted that the various drawings are not to scale.

### DETAILED DESCRIPTION

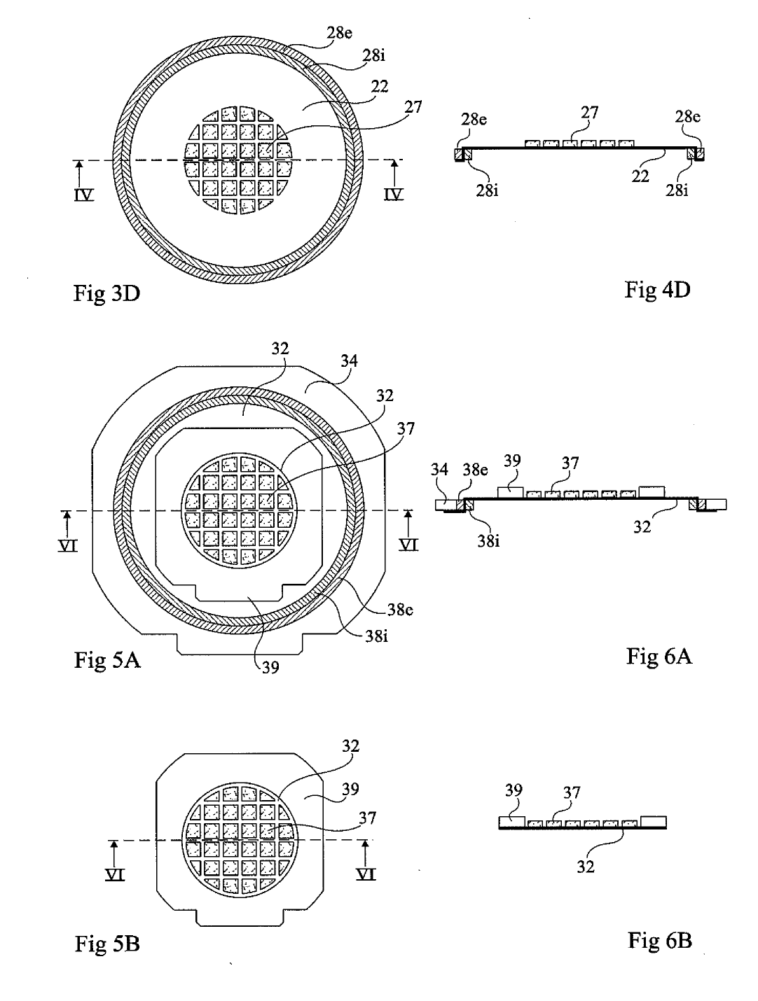

FIGS. 5A, 6A and 5B, 6B schematically illustrate steps of a method for manufacturing semiconductor chips, comprising a step of dicing of a semiconductor wafer into individual chips by means of a laser beam. FIGS. 5A and 5B are top views and FIGS. 6A and 6B respectively are cross-section views along planes VI-VI of FIGS. 5A and 5B.

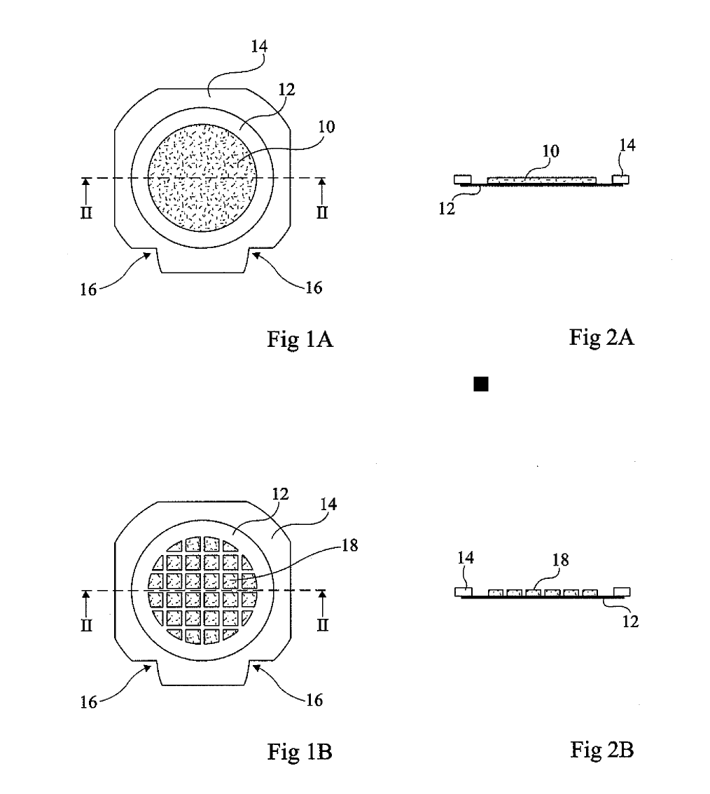

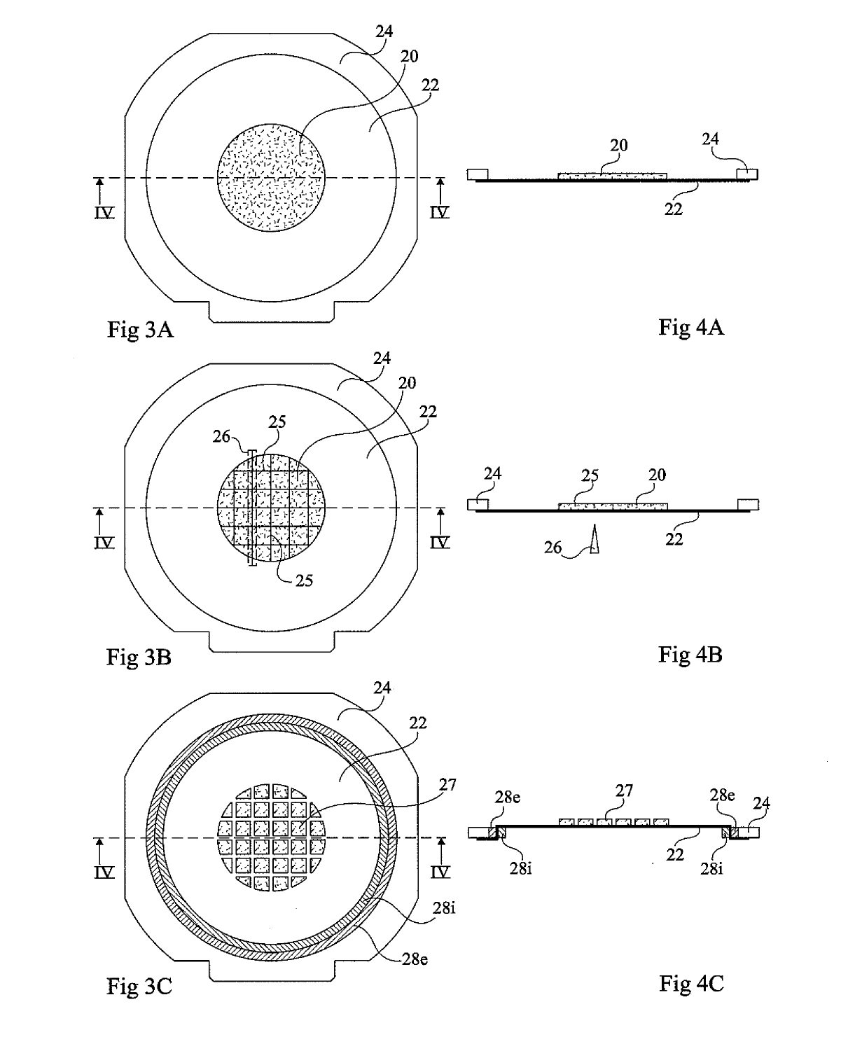

It is here provided to perform a laser dicing according to a method of the type described in relation with FIGS. 3A to 4C. For this purpose, the semiconductor wafer is placed on an elastic film 32 stretched on a support frame 34. It has been seen previously that to be able to perform a dicing by means of a laser beam, the inner diameter of frame 34 has to be greater by at least from 2 to 3 centimeters than the wafer diameter (for wafers having a 20-centimeter diameter). It is here provided to use a support frame 34 having an inner diameter much greater than the wafer diameter and greater than the outer dimensions of a conventional support frame of the type described in relation with FIGS. 1A to 2B. As an example, to dice wafers having a diameter of 15 or 20 cm, it is here provided to use a frame 34 with an inner diameter of approximately 30 cm.

Elastic film 32, for example, is an adhesive film with a thickness approximately ranging from 70 to 200 μm. The adhesiveness of the film enables to easily bond the film to the frame and the wafer to the film. However, if film 32 is not adhesive, it may be provided to bond the film to the frame and/or the wafer to the film by means of glue or by any other adapted bonding means.

In this example, the wafer is diced into individual chips 37 according to a method of the type described in relation with FIGS. 3B and 4B especially comprising a step of forming, by means of a laser beam, of a grid of grooves on a surface of the wafer, and a step of wafer breakage along each groove of the grid by means of a knife. Chips 37 are then separated from one another by the extension of elastic film 32 caused by extension rings 38e and 38i, according to a method similar to that described in relation with FIGS. 3C and 4C.

FIGS. 5A and 6A schematically show film 32, support frame 34, individual chips 37, and outer and inner extension rings 38e and 38i after the above-mentioned wafer dicing and film extension operations.

FIGS. 5A and 6A further illustrate a step of placing, on film 32, between inner extension ring 38i and the diced wafer, of an additional support frame 39, having dimensions smaller than the inner diameter of ring 38i and an inner diameter slightly greater than the diameter of the diced wafer. Frame 39 actually is a frame of standard shape and dimensions, conventionally used to perform sawing operations (frame 14 of FIGS. 1A and 2A), and compatible with the existing machines of a given manufacturing line. If film 32 is adhesive, frame 39 will be simply laid on an adhesive surface of the film. If film 32 is not adhesive, frame 39 may be bonded to the film by any adapted means, for example, by means of glue.

FIGS. 5B and 6B illustrate a step during which frame 34 and extension rings 38 (FIGS. 5A and 6A) are removed, for example by cutting of film 32 between the vicinity of the outer contour of frame 39 and the inner contour of ring 38i. Frame 39 then forms a new support for the diced wafer, this new support having the advantage of being compatible with the existing machines of a given production chain.

More generally, it is here provided, to dice a semiconductor wafer into chips by means of a laser beam, to:
arrange the wafer on a surface of an elastic film stretched on a first frame having an inner diameter much greater than the wafer dimensions, so that in top view, a ring-shaped film portion separates the outer contour of the wafer from the inner contour of the frame;
carrying out the dicing by using equipment capable of receiving the first frame;
arranging, on the ring-shaped film portion, a second support frame having smaller dimensions than the first frame;
cutting the film between the vicinity of the outer contour of the second frame and the inner contour of the first frame and removing the first frame; and
carrying out manufacturing steps on the diced wafer, by using equipment capable of receiving the second frame.

It will be ascertained that the dimensions of the first frame are large enough so that, after the dicing, the width of the ring-shaped film portion between the diced semiconductor wafer and the first frame (or the extension rings) is sufficient to receive the second frame. As an example, the width of the ring-shaped film portion will range between 7 and 15 centimeters for wafers having a diameter of 15 or 20 centimeters.

An advantage of this method is that it enables, by a relatively simple operation, to carry out a laser dicing and then return to an existing production line without having to change or redimension the equipment intended to implement manufacturing steps subsequent to the wafer dicing.

More generally, such a method may be implemented for any manufacturing step requiring the use of a frame having dimensions greater than the dimensions of the standard support frame of a given production line.

Specific embodiments have been described. Various alterations and modifications will occur to those skilled in the art. In particular, an example of a method in which a semiconductor wafer, support frames 34 and 39, and an outer extension ring 38e are attached on the upper surface side of an elastic film 32, and in which an extension ring 38i is attached on the lower surface side of film 32 has been described and illustrated. It should be noted that each of these elements may be indifferently placed over or under film 32, while however making sure that rings 38e and 38i are placed on either side of film 32.

It should further be noted that the wafer and the support frames may have any other shape than those shown hereabove. In particular, the support frames may have a non-circular inner contour.

Further, the present invention is not limited to the numerical values, and especially to the frame dimensions, mentioned hereabove as an example.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method for manufacturing semiconductor chips from a semiconductor wafer, comprising the steps of:
a) arranging the wafer on a surface of an elastic film stretched on a first support frame having dimensions much greater than the wafer dimensions, so that, in top view, a ring-shaped film portion separates the outer contour of the wafer from the inner contour of the frame;
b) carrying out manufacturing operations by using equipment capable of receiving the first frame;
c) arranging, on the ring-shaped film portion, a second support frame of smaller outer dimensions than the inner dimensions of the first frame;
d) cutting the film between the vicinity of the outer contour of the second frame and the inner contour of the first frame and removing the first frame; and
e) carrying out manufacturing operations by using equipment capable of receiving the second frame.

2. The method of claim 1, wherein the wafer has a generally circular shape, and the first and second frames have circular inner contours of diameters respectively greater than and at least equal to the wafer diameter.

3. The method of claim 1, wherein the first and second frames have outer contours of generally square shape with rounded corners, with location notches.

4. The method of claim 1, wherein the operations carried out at step b) comprise an operation of dicing of the wafer into chips applying a laser beam and by hitting with a knife.

5. The method of claim 4, wherein step b) further comprises, after the wafer dicing into chips, a step of separation of the chips by extension of the film by means of a pair of extension rings.

6. The method of claim 5, wherein the ring-shaped film portion has a sufficient width to receive the second frame after the step of separation of the chips by means of the extension rings.

7. The method of claim 1, wherein the elastic film is an adhesive film.

8. The method of claim 1, wherein the width of the ring-shaped film portion ranges between 7 and 15 centimeters.

9. The method of claim 2, wherein the wafers have a diameter of 15 or 20 centimeters.
